(19) United States
(12) Patent Application Publication
(10) Pub. No.: US 2015/0246845 A1
(43) Pub. Date: Sep. 3, 2015

(54) METHOD FOR FORMING THIN FILM

(71) Applicant: Asahi Glass Company, Limited, Chiyoda-ku (JP)

(72) Inventors: Atsushi Seki, Tokyo (JP); Wataru Nishida, Tokyo (JP); Kuniaki Hiromatsu, Tokyo (JP)

(73) Assignee: Asahi Glass Company, Limited, Chiyoda-ku (JP)

(21) Appl. No.: 14/716,181

(22) Filed: May 19, 2015

Related U.S. Application Data
(63) Continuation of application No. PCT/JP2013/081673, filed on Nov. 25, 2013.

(30) Foreign Application Priority Data
Nov. 26, 2012 (JP) 2012-257227

(51) Int. Cl. C03C 17/245; C23C 16/44; C23C 16/455; C23C 16/40

(52) U.S. Cl. CPC C03C 17/245; C23C 16/402; C23C 16/44; C23C 16/455

(57) ABSTRACT

A method for forming a SiO₂ thin film on a glass substrate by an online atmospheric pressure CVD method, which uses, as a raw material gas supply means, a post mixing type raw material supply means of separately supplying a process gas 1 which contains monosilane (SiH₄) as a main raw material gas and a process gas 2 which contains oxygen (O₂) as an auxiliary raw material gas and mixing the process gases 1 and 2 on the glass substrate, wherein the flow rate of the monosilane (SiH₄) per unit width is at least 1.0 NL/min·m, and the process gas 1 contains ethylene (C₂H₄) in an amount such that the concentration ratio to the monosilane (SiH₄) (C₂H₄ (mol %)/SiH₄ (mol %)) is at most 3.2, whereby the deposition rate for forming a SiO₂ thin film is improved.

### TECHNICAL FIELD

The present invention relates to a method for forming a thin film. Specifically, it relates a method for forming a SiO₂ thin film on a glass substrate by an online atmospheric pressure CVD method.

### BACKGROUND ART

A SiO₂ thin film formed on a substrate such as glass is useful as a various functional thin film. For example, it is useful as a layer constituting a part of an antireflection film, a layer constituting a part of a ultraviolet (UV) blocking multilayer structure, a layer constituting a part of an infrared (IR) blocking multilayer structure, a surface layer for Low-E (Low-emissivity) glass or a reflection amplifying layer of a sunlight collecting glass, or at the time of producing a thin film type solar cell, it is used also as a various functional film to be formed on a glass substrate constituting a transparent substrate for the thin film type solar cell, specifically as an alkali barrier layer or as an intermediate refractive index layer formed between a glass substrate and a tin oxide film constituting a transparent conductive film.

As mentioned above, a SiO₂ thin film may be formed on a glass substrate for various purposes, and a method of forming a SiO₂ thin film on a glass substrate by a CVD method has been proposed.

For example, Patent Document 1 proposes a method for forming a SiO₂ thin film on a glass ribbon by a CVD method by utilizing a residual heat in the process for producing a float glass ribbon.

In the method disclosed in Patent Document 1, a SiO₂ thin film is formed on a glass ribbon by supplying a precursor mixture comprising monosilane, a radical scavenger, oxygen and a carrier gas to the surface of a glass ribbon being transported in a float glass tank enclosure (i.e. in a float bath). As the radical scavenger to prevent ignition of a precursor gas and to adjust the reaction rate of the precursor mixture, ethylene is said to be preferred, and the ratio of ethylene to the monosilane (ethylene:monosilane) in the precursor mixture is disclosed to be within a range of from about 3:1 to 17:1, preferably about 9:1.

In Patent Document 1, a precursor mixture comprising monosilane, a radical scavenger, oxygen and a carrier gas is supplied onto a glass substrate in order to apply a CVD method online to the glass ribbon being transported in the float bath. Hereinafter, in this specification, a procedure to apply a CVD method to a glass ribbon being transported in a float bath, or, as described later, a procedure to apply a CVD method to a plate glass which has come out from a float bath and is in an annealing process, will be referred to as an “online CVD method”.

In a case where an online CVD method is applied to a glass ribbon being transported in a float bath, it is preferred to employ a premixing type raw material gas supply means of supplying a precursor mixture having raw materials for forming a SiO₂ thin film preliminarily mixed, on the glass ribbon, for such reasons that the nozzle structure for supplying the raw material gas will be simplified, and the raw material gas utilization efficiency will be high.

However, in the case of using such a premixing type raw material gas supply means, it is necessary to mix ethylene, as a radical scavenger to prevent ignition of the precursor gas and to adjust the reaction rate of the precursor mixture, to the precursor gas in such an amount that its ratio to monosilane (ethylene:monosilane) will be in a range of from about 3:1 to 17:1, preferably about 9:1. If ethylene is mixed in such an amount to the precursor gas, the resulting SiO₂ thin film is likely to contain carbon. If the resulting SiO₂ thin film contains carbon, the light transmittance is likely to be low due to absorption by the film itself.

On the other hand, if a post mixing type raw material gas supply means of separately supplying oxygen and monosilane to be used as raw material for a SiO₂ thin film and mixing them directly on the glass substrate, is employed, a radical scavenger becomes unnecessary, and the above mentioned problem relating to light transmittance will be resolved.

In the case of applying an online atmospheric pressure CVD method to a plate glass which has come out from a float bath and is in an annealing process, it is possible to reduce the possibility of contamination as compared to the case of conducting an online CVD method within a float bath, and further, it is possible to control the temperature at the time of conducting the CVD method, whereby there is a merit such that it is possible to adjust the composition and constitution of the film to be formed.

On the other hand, if the post mixing type raw material supply means is employed when applying the online CVD method to a plate glass which has come out from a float bath and is in an annealing process, it becomes difficult to increase the deposition rate.

That is, in the post mixing type raw material supply means of separately supplying raw material gases and mixing them directly on the glass substrate, mixing of the raw material gases is likely to be insufficient, and consequently, progress of the reaction tends to be slow, and the deposition rate tends to be low, as compared with the premixing type raw material gas supply means of preliminarily mixing the raw material gases and then supplying the mixed gas on the glass substrate.

### PRIOR ART DOCUMENT

### Patent Document

Patent Document 1: Japanese Patent No. 4,290,760

### DISCLOSURE OF INVENTION

### Technical Problem

In view of the above-mentioned problem in the prior art, it is the main object of the present invention to improve the deposition rate when forming a SiO₂ thin film on a glass substrate by applying an online atmospheric pressure CVD method to a plate glass which has come out from a float bath and is in an annealing process.

### Solution to Problem

In order to accomplish the above object, the present inventors have conducted an extensive study and as a result, have found that when a very small amount of ethylene is mixed to monosilane which is supplied from the post mixing type raw material gas supply means, the deposition rate for a SiO₂ thin film is improved. On the other hand, it has also been found that in the case of using the post mixing type raw material gas supply means, if ethylene is used in such an amount as used as a radical scavenger in the case of the premixing type, i.e. in an excessive amount to the monosilane, the deposition rate for a SiO₂ thin film tends to be low.

The present invention has been accomplished based on the above findings and provides a method for forming a SiO₂ thin film on a glass substrate by an online atmospheric pressure CVD method, which uses, as a raw material gas supply means, a post mixing type raw material supply means of separately supplying a process gas 1 which contains monosilane (SiH₄) as a main raw material gas and a process gas 2 which contains oxygen (O₂) as an auxiliary raw material gas and mixing the process gases 1 and 2 on the glass substrate, wherein the flow rate of the monosilane (SiH₄) per unit width is at least 1.0 NL/min·m, and the process gas 1 contains ethylene (C₂H₄) in an amount such that the concentration ratio to the monosilane (SiH₄) (C₂H₄ (mol %)/SiH₄ (mol %)) is at most 3.2.

In an embodiment of the method for forming a SiO₂ thin film of the present invention, it is preferred that the process gas 1 contains ethylene (C₂H⁴) in an amount such that the concentration ratio to the monosilane (SiH₄) (C₂H₄ (mol %)/SiH₄ (mol %)) is from 0.2 to 3.2.

In an embodiment of the method for forming a SiO₂ thin film of the present invention, it is preferred that the flow rate of the monosilane (SiH₄) per unit width is at least 1.5 NL/min·m.

In an embodiment of the method for forming a SiO₂ thin film of the present invention, it is preferred that the process gas 1 is a mixed gas comprising monosilane (SiH₄), ethylene (C₂H₄) and an inert gas, and the concentration of the monosilane (SiH₄) in the process gas 1 is from 0.2 to 2 mol %.

In the method for forming a SiO₂ thin film of the present invention, the molar ratio of the oxygen (O₂) in the process gas 2 to the monosilane (SiH₄) in the process gas 1 (O₂SiH₄) is preferably at least 5, more preferably at least 20.

In an embodiment of the method for forming a SiO₂ thin film of the present invention, it is preferred that the deposition rate for the SiO₂ thin film is at least 425 nm·m/min.

### Advantageous Effect of Invention

According to the present invention, it is possible to improve the deposition rate at the time of forming a SiO₂ thin film on a glass substrate by applying an online atmospheric pressure CVD method to a plate glass which has come out from a float bath and is in an annealing process.

### BRIEF DESCRIPTION OF DRAWINGS

FIG. 1 is a view schematically illustrating one constructional example of the raw material gas supply means to be used in the method for forming a SiO₂ thin film of the present invention.

FIG. 2 is a graph wherein a relation between the flow rate per unit width (NL/min·m) of SiH₄ in the process gas 1 and the deposition rate (nm·m/mm) for a SiO₂ thin film is plotted.

FIG. 3 is a graph wherein a relation between the concentration ratio (molar ratio) of C₂H₄ to SiH₄ in the process gas 1 and the deposition rate (nm·m/mm) for a SiO₂ thin film is plotted.

FIG. 4 is a graph wherein a relation between the concentration ratio (molar ratio) of C₂H₄ to SiH₄ in the process gas 1 and the deposition rate (nm·m/mm) for a SiO₂ thin film is plotted.

FIG. 5 is a graph wherein a relation between the O₂/SiH₄ supply molar ratio and the deposition rate (nm·m/mm) for a SiO₂ thin film is plotted.

FIG. 6 is a graph wherein a relation between the SiH₄ concentration (mol %) in the process gas 1 and the deposition rate (nm·m/mm) for a SiO₂ thin film is plotted.

FIG. 7 is a graph wherein a relation between the SiH₄ concentration (mol %) in the process gas 1 and the deposition rate (nm·m/mm) for a SiO₂ thin film/flow rate per unit width (NL/min·m) of SiH₄ is plotted.

### DESCRIPTION OF EMBODIMENTS

Now, the method for forming a SiO₂ thin film of the present invention will be described with reference to the drawings.

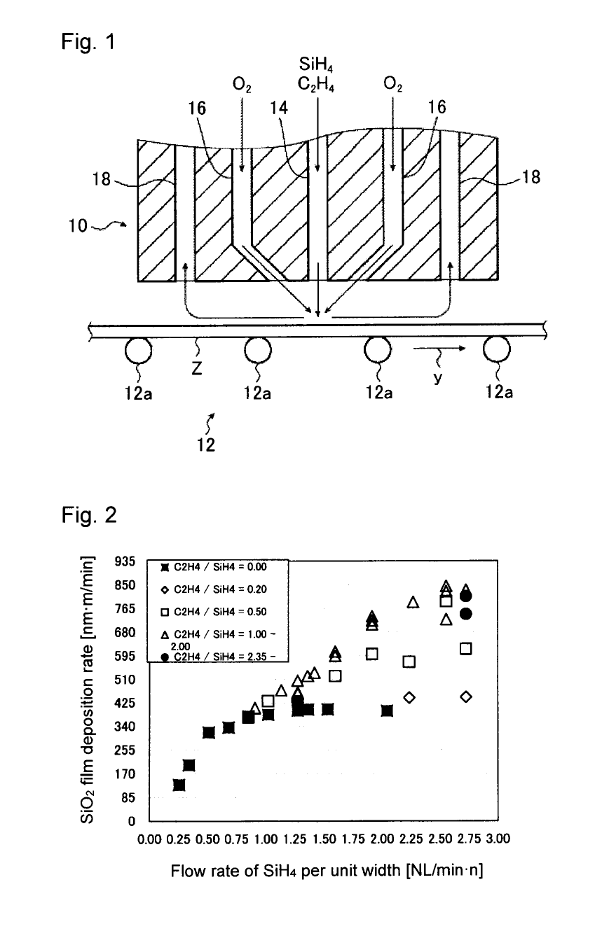

FIG. 1 is a view schematically illustrating one constructional example of the raw material gas supply means to be used in the method for forming a SiO₂ thin film of the present invention.

The raw material gas supply means 10 shown in FIG. 1 is a means of supplying raw material gases to a glass substrate Z which is transported in the direction of arrow y by rollers 12a of a roller conveyor 12.

The raw material gas supply means 10 shown in FIG. 1 comprises a nozzle (main raw material nozzle) 14 for supplying a main raw material gas, nozzles (auxiliary raw material nozzles) 16, 16 for supplying an auxiliary raw material gas and exhaust nozzles 18, 18 for suctioning for withdrawal of a gas formed by the reaction or an excess raw material gas.

The gas supply means 10 having such a construction is disposed above the glass substrate Z with a space of from 3 mm to 30 mm. Thus, the lower surface of the gas supply means 10 is disposed to face the glass substrate Z being transported, with a space of from 3 mm to 30 mm. The smaller the space, the more advantageous for the film thickness or film quality during the film deposition, but, if the space is varied by warpage or vibration of the glass ribbon, the influence to the film thickness or film quality will increase. Further, if the space is large, the raw material utilization efficiency during the film deposition tends to be low. The space is preferably from 4 to 15 mm, more preferably from 5 to 12 mm.

The raw material gas supply means 10 shown in FIG. 1 is a post mixing type raw material supply means of mixing a main raw material gas from the main raw material nozzle 14 and an auxiliary raw material gas from the auxiliary raw material nozzles 16, 16 on the glass substrate Z.

In the method for forming a SiO₂ thin film of the present invention, the process gas 1 supplied from the main raw material nozzle 14 contains, in addition to monosilane (SiH4) as a main raw material gas, ethylene (C₂H₄) in an amount such that the molar concentration ratio of ethylene (C₂H₄) to the monosilane (SiH₄) (C₂H₄ (mol %)/SiH₄ (mol %)) is at most 3.2, preferably from 0.1 to 3.

As mentioned above, in the case of using a premixing type raw material gas supply means of supplying materials to form a SiO₂ thin film in the form of a preliminarily mixed precursor mixture, it was necessary to mix ethylene, as a radical scavenger to prevent ignition of the precursor gas and adjust the reaction rate of the precursor mixture, to the precursor gas in such an amount that the ratio of ethylene to monosilane (ethylene:monosilane) would be in a range of from about 3:1 to 17:1, preferably about 9:1.

Whereas, in the case of using a post mixing type raw material gas supply means, monosilane (SiH₄) as a main raw material gas and oxygen (O₂) as an auxiliary raw material gas are separately supplied and mixed directly on a glass substrate, whereby it is unnecessary to use ethylene as a radical scavenger, and it used to be considered that use of ethylene should be avoided in consideration of a possibility that the resulting SiO₂ thin film would contain carbon and that the light transmittance would decrease if the film contained carbon.

However, the present inventors have confirmed that the deposition rate for a SiO₂ thin film is improved when, in addition to monosilane (SiH₄) as the main raw material gas, a very small amount of ethylene (C₂H₄) is incorporated to the process gas 1 to be supplied from the main raw material nozzle 14. The present inventors consider the reason to be as follows.

If no ethylene (C₂H₄) is incorporated to the process gas 1, monosilane (SiH₄) and oxygen (O₂) will vigorously be reacted on the glass substrate Z. As a result, part of SiO₂ formed by the reaction is powdered and dispersed around without forming a SiO₂ thin film on the glass substrate Z. On the other hand, when ethylene (C₂H₄) is incorporated to the process gas 1, the reaction of monosilane (SiH₄) and oxygen (O₂) on the glass substrate Z will be mild. As a result, SiO₂ being powdered and dispersed around will decrease, and SiO₂ contributing to formation of a SiO₂ thin film will increase. Thus, the deposition rate for a SiO₂ thin film will be improved.

However, in the case of using the post mixing type raw material gas supply means, if ethylene is mixed in an amount to be mixed as a radical scavenger in the case of the premixing type, i.e. in an excess amount to monosilane, the deposition rate for a SiO₂ thin film will remarkably decrease.

The present inventors consider the reason for this to be such that the reaction of monosilane (SiH₄) and oxygen (O₂) on the glass substrate Z tends to be too mild.

When ethylene (C₂H₄) is incorporated to the process gas 1 containing monosilane (SiH₄), the deposition rate is improved.

However, if the content of ethylene (C₂H₄) is larger than 3.2 by its concentration ratio to monosilane (SiH₄) (C₂H₄ (mol %)/SiH₄ (mol %)), the reaction of monosilane (SiH₄) and oxygen (O₂) in a gas phase tends to be suppressed too much, whereby the deposition rate for a SiO₂ thin film rather tends to decrease.

The content of ethylene (C₂H₄) is preferably from 0.2 to 3.2, more preferably from 0.5 to 3.2 by its concentration ratio to monosilane (SiH₄) (C₂H₄ (mol %)/SiH₄ (mol %)).

Therefore, the process gas 1 is supplied in the form of a mixed gas comprising monosilane (SiH₄), ethylene (C₂H₄) and a rare gas, from the main raw material nozzle 14.

Here, the monosilane (SiH₄) concentration in the process gas 1 is preferably from 0.60 to 1.75 mol %.

If the monosilane (SiH₄) concentration in the process gas 1 is higher than 1.75 mol %, the deposition rate for a SiO₂ thin film rather tends to decrease.

The monosilane (SiH₄) concentration in the process gas 1 is more preferably from 0.60 to 1.50 mol %.

As the process gas 2 to be supplied from auxiliary raw material nozzles 16, 16, usually, only oxygen (O₂) is supplied as an auxiliary raw material gas, but a rare gas may be incorporated unless the deposition rate for a SiO₂ thin film would not be thereby distinctly lowered. When a rare gas is to be incorporated to the process gas 2, its concentration is preferably at least 5 mol %, more preferably at least 10 mol %, so long as oxygen (O₂) in the process gas 2 is present in an amount sufficient for the reaction. As such a rare gas, nitrogen, argon or helium may, for example, be mentioned.

In the present invention, the molar ratio (O₂SiH₄) of oxygen (O₂) in the process gas 2 which is supplied from auxiliary raw material nozzles 16, 16, to monosilane (SiH₄) in the process gas 1 which is supplied from the main raw material nozzle 14, is preferably at least 5, more preferably at least 20.

If the molar ratio (O₂/SiH₄) of oxygen (O₂) in the process gas 2 to monosilane (SiH₄) in the process gas 1, is lower than 5, there will be such a problem that the deposition rate tends to be slow.

The upper limit for the molar ratio (O₂/SiH₄) of oxygen (O₂) in the process gas 2 to monosilane (SiH₄) in the process gas 1, is not particularly limited so long as it is sufficient for the reaction, and is usually at most 250.

In the present invention, with a view to improving the deposition rate for a SiO₂ thin film, it is preferred to adjust the discharge flow rate of the process gas 1 which is supplied from the main raw material nozzle 14 and the discharge flow rate of the process gas 2 which is supplied from the auxiliary raw material nozzles 16, 16 so that they become proper conditions.

In the present invention, the ratio of the discharge flow rate (N·cm/s) of the process gas 1 to the discharge flow rate (N·cm/s) of the process gas 2 is preferably adjusted to be from 1:2 to 10:1.

If the discharge flow rate (N·cm/s) of the process gas 1 is lower than 1:2 by its ratio to the discharge flow rate (N·cm/s) of the process gas 2, the deposition rate for a SiO₂ thin film may sometimes decrease.

Also if the discharge flow rate (N·cm/s) of the process gas 1 is higher than 10:1 by its ratio to the discharge flow rate (N·cm/s) of the process gas 2, the deposition rate for a SiO₂ thin film may sometimes decrease.

The ratio of the discharge flow rate (N·cm/s) of the process gas 1 to the discharge flow rate (N·cm/s) of the process gas 2 is adjusted to be more preferably from 1:2 to 4:1, further preferably from 1:1 to 4:1.

In the present invention, the discharge flow rate of the process gas 1 which is supplied from the main raw material nozzle 14 is preferably at least 10 N·cm/s. Otherwise, the deposition rate tends to be too low, for such a reason that the amount of the process gas 1 reaching the substrate tends to decrease. On the other hand, there is no particular limitation set for the upper limit for the discharge flow rate of the process gas 1. However, if it is too high, the deposition rate is rather likely to decrease, or the outer appearance of the film is likely to be adversely affected, and therefore, the upper limit may be set within a range where such a disadvantage will not occur. The discharge flow rate of the process gas 1 is usually at most 200 N·cm/s.

In the present invention, the discharge flow rate of the process gas 2 which is supplied from the auxiliary raw material nozzles 16, 16 is preferably at least 10 N·cm/s. If the discharge flow rate of the process gas 2 is low, the deposition rate tends to be too low, for such a reason that the amount of O₂ reaching the substrate tends to decrease. On the other hand, there is no particular limitation set for the upper limit for the discharge flow rate of the process gas 2. However, if it is too high, the deposition rate is rather likely to decrease, or the outer appearance of the film is likely to be adversely affected, and therefore, the upper limit may be set within a range where such a disadvantage will not occur. The discharge flow rate of the process gas 2 is usually at most 200 N·cm/s.

In the present invention, the temperature of the glass substrate Z at the time of supplying the process gases 1 and 2 is preferably from 500 to 650° C.

If the temperature of the glass substrate Z is lower than 500° C., there will be such a problem that the reaction rate of monosilane (SiH₄) and oxygen (O₂) tends to decrease, and the deposition rate tends to be too low. On the other hand, if the temperature of the glass substrate Z is higher than 650° C., such a temperature is close to the strain point or softening point of the glass substrate, and there will be such a problem that the substrate is likely to be adversely affected.

The temperature of the glass substrate Z is more preferably at least 540° C. and at most 620° C. from the viewpoint of consistency with the online process in the production of a glass plate.

Now, the method for forming a SiO₂ thin film of the present invention will be further described.

### <Glass Substrate>

The glass substrate for forming a SiO₂ thin film by the method of the present invention is not particularly limited. Various glass substrates may be employed depending upon the purposes of SiO₂ thin films to be formed.

In a case where a SiO₂ thin film is formed as an alkali barrier layer, the glass substrate is a glass substrate containing mainly an alkali component, and a glass substrate made of soda lime silicate glass may be exemplified. Further, after forming the SiO₂ thin film, if a tin oxide film is formed as a transparent conductive film, the SiO₂ thin film will function also as an intermediate refractive index layer.

Further, such a SiO₂ thin film as an intermediate refractive index layer may be formed also on an alkali free glass substrate containing no alkali component.

### <SiO₂ Thin Film>

The film thickness of the SiO₂ thin film to be formed on the glass substrate may suitably be selected depending upon the purpose for forming the SiO₂ thin film.

In a case where a SiO₂ thin film is formed as an alkali barrier layer or an intermediate refractive index layer, its thickness is preferably from 20 to 100 nm.

In a case where a SiO₂ thin film is formed as a layer constituting a part of an antireflection film, a layer constituting a part of a ultraviolet (UV) blocking multilayer structure, a layer constituting a part of an infrared (IR) blocking multilayer structure, or a surface layer for Low-E (Low-emissivity) glass, the film thickness is preferably as follows.

A layer constituting a part of a three layered antireflection film: from 80 to 120 nm.

A layer constituting a part of a four layered antireflection film: from 70 to 110 nm.

A layer constituting a part of a UV blocking multilayer structure: from 40 to 80 nm.

A layer constituting a part of a IR blocking multilayer structure: at most 200 nm.

A surface layer for Low-E glass: from 20 to 220 nm.

### EXAMPLES

Now, the present invention will be described in detail with reference to Examples. However, it should be understood that the present invention is by no means limited thereto.

In the following Examples and Comparative Examples, a soda lime silicate glass substrate having a thickness of 4 mm was used as the glass substrate, and a SiO₂ thin film was formed on the glass substrate by means of a conveyor-type atmospheric pressure CVD apparatus. The raw material gas supply means of the conveyor-type atmospheric pressure CVD apparatus has the construction as shown in FIG. 1.

From the main raw material nozzle 14 of the raw material gas supply means as shown in FIG. 1, a mixed gas comprising monosilane (SiH₄), ethylene (C₂H₄) and a rare gas (nitrogen gas), was supplied as the process gas 1. From the auxiliary raw material nozzles 16, 16, oxygen (O₂) was supplied as the process gas 2. The SiH₄ concentration (mol %), C₂H₄ concentration (mol %) and concentration ratio (molar ratio) of C₂H₄ to SiH₄ (C₂H₄/SiH₄) in the process gas 1, the discharge flow rates (Ncm/s) of the process gases 1 and 2, the O₂ concentration (mol %) in the process gas 2, the molar ratio (O₂/SiH₄) of oxygen (O₂) in the process gas 2 to monosilane (SiH₄) in the process gas 1, the flow rate of SiH₄ per unit width (NL/min·m) and the substrate temperature (° C.) are shown in the following Tables 1, 2-1, 2-2, 2-3, 3 and 4.

The deposition rate (nm·m/min) for a SiO₂ thin film was measured by the following procedure.

Using a film thickness meter (FFB, manufactured by System Road Co., Ltd.), the film thickness at one point in the vicinity of the center in a width direction of a glass substrate was measured. At that time, as the refractive indices of SiO₂, the following Table 5 was used. Further, in order to facilitate the distinction between the glass substrate and the formed SiO₂ layer and to increase the precision in measurement of the film thickness, a TiO₂ film as a high refractive index layer was inserted between the glass substrate and the SiO₂ film.

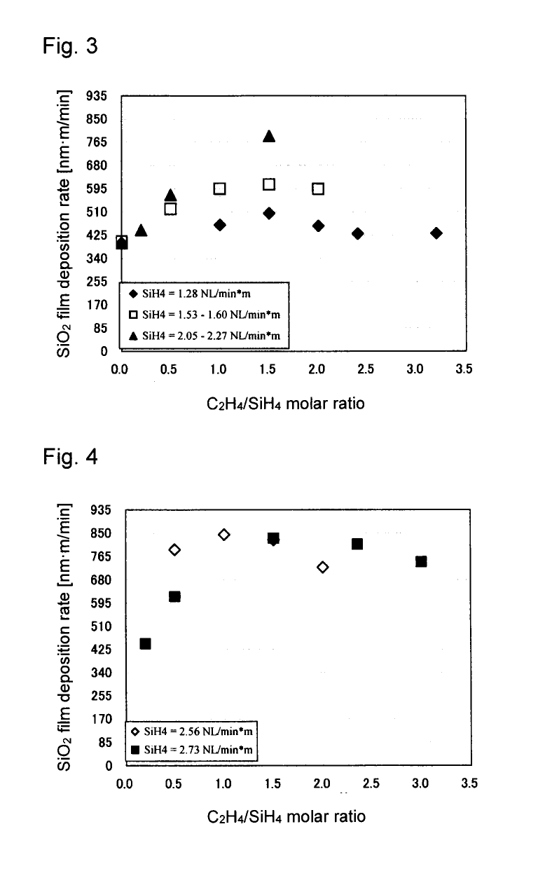

FIG. 2 is a graph wherein the relation between the flow rate of SiH₄ per unit width (NL/min·m) and the deposition rate for a SiO₂ thin film (nm·m/min) was plotted with respect to the conditions in Comparative Examples in Table 1 and in Examples in Tables 2-1, 2-2 and 2-3. As is evident from FIG. 2, in each of Comparative Examples 1 to 10 wherein no C₂H₄ was added and Comparative Examples 11 and 12 wherein the flow rate of SiH₄ per unit width (NL/min·m) was less than 1.0, the deposition rate for a SiO₂ thin film was low at a level of less than 425 nm·m/min. Whereas, it is seen that in a case where C₂H₄ was added, the deposition rate for a SiO₂ thin film was improved at a level of at least 425 nm·m/min., when the flow rate of SiH₄ per unit width (NL/min·m) was at least 1.0.

Here, the flow rate per unit width (NL/min·m) is the flow rate of the gas supplied per unit time from a unit width of a gas supply means (e.g. an injector) disposed substantially perpendicular to the transportation direction of the glass substrate, and is here represented by the gas supplied per a width of 1 m of the gas supply means per one minute as calculated as a gas volume in a standard state.

FIG. 3 is a graph wherein the relation between the concentration ratio (molar ratio) of C₂H₄ to SiH₄ in the process gas 1 and the deposition rate (nm·m/min) for a SiO₂ thin film was plotted every time when the flow rate of SiH₄ per unit width (NL/min·m) was changed.

As is evident from FIG. 3, as compared with Comparative Examples 7, 9 and 10 wherein the process gas 1 contained no C2H4, in each of Examples wherein C₂H₄ was added, the deposition rate for a SiO₂ thin film was improved up to its concentration ratio to SiH₄ (C₂H₄ (mol %)/SiH₄ (mol %)) being 3.2. Here, in FIG. 3, in Examples 9, 14, 22 , 26 and 29, the flow rate per unit width was 1.28 (NL/min·m), in Examples 4, 10, 17 and 23, the flow rate per unit width was from 1.53 to 1.60 (NL/min·m), and in Examples 1, 6 and 19, the flow rate per unit width was from 2.05 to 2.27 (NL/min·m).

FIG. 4 is a graph wherein the relation between the concentration ratio (molar ratio) of C₂H₄ to SiH₄ in the process gas 1 and the deposition rate (nm·m/min) for a SiO₂ thin film was plotted with respect to Examples 2, 8, 21, 27 and 28 wherein the SiH₄ concentration in the process gas 1 was 1.28 mol %, and Examples 7, 12, 20 and 25 wherein the SiH₄ concentration was 1.50 mol %.

In these Examples, by incorporating C₂H₄ to the process gas 1, it was possible to incorporate SiH-₄ at a concentration exceeding the explosion limit in the case of not incorporating C₂H₄.

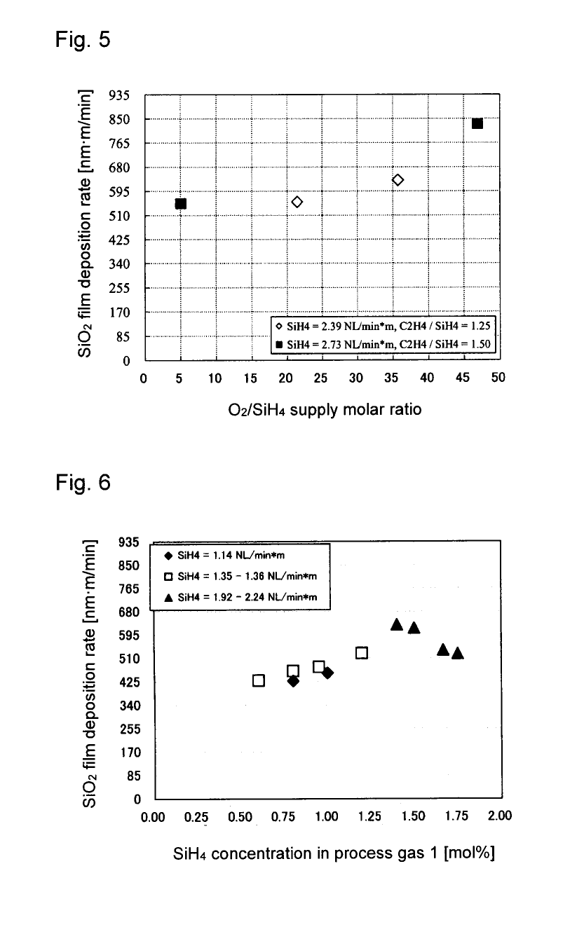

FIG. 5 is a graph wherein the relation between the O₂/SiH₄ supply molar ratio in the process gases and the deposition rate (nm·m/mm) for a SiO₂ thin film is plotted.

As is evident from FIG. 5, a high deposition rate for a SiO₂ thin film is accomplished when the O₂/SiH₄ supply molar ratio is at least 5.

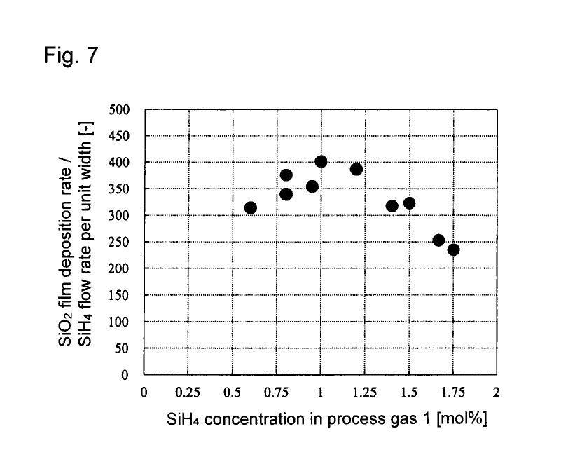

FIG. 6 is a graph wherein the relation between the SiH₄ concentration (mol %) in the process gas 1 and the deposition rate (nm·m/mm) for a SiO₂ thin film is plotted. Further, FIG. 7 is a graph wherein the relation between the SiH₄ concentration (mol %) in the process gas 1 and the value obtained by dividing the deposition rate (nm·m/mm) for a SiO₂ thin film by the flow rate per unit width (NL/min·m) of SiH₄ is plotted.

As is evident from FIG. 6, at any SiH₄ concentration, the deposition rate for a SiO₂ thin film is improved when the SiH₄ concentration (mol %) is high.

On the other hand, as is evident from FIG. 7, at a SiH₄ concentration of 1.5 mol % or higher, the value obtained by dividing the deposition rate (nm·m/mm) for a SiO₂ thin film by the flow rate per unit width (NL/min·m) of SiH₄, which indicates the utilization efficiency of SiH⁴ as raw material in the process gas, is lowered. This is considered to be such that when the Sifts concentration (mol %) is made high, the deposition efficiency relative to the supply amount of SiH₄ raw material decreases, and the ratio of SiH₄ not utilized for film deposition increases.

TABLE 1

| | | | Comp. | Comp. | Comp. | Comp. | Comp. | Comp. | Comp. | Comp. | Comp. | Comp. | Comp. | Comp. |
|---|---|---|---|---|---|---|---|---|---|---|---|---|---|---|
| | | | Ex. 1 | Ex. 2 | Ex. 3 | Ex. 4 | Ex. 5 | Ex. 6 | Ex. 7 | Ex. 8 | Ex. 9 | Ex. 10 | Ex. 11 | Ex. 12 |
| Process | SiH₄ | [mol %] | 0.20 | 0.27 | 0.30 | 0.40 | 0.50 | 0.60 | 1.00 | 0.80 | 1.20 | 0.80 | 0.60 | 0.80 |
| gas 1 | concentra- | | | | | | | | | | | | | |
| | tion | | | | | | | | | | | | | |
| | C₂H₄ | [mol %] | 0.00 | 0.00 | 0.00 | 0.00 | 0.00 | 0.00 | 0.00 | 0.00 | 0.00 | 0.00 | 0.30 | 1.20 |
| | concentra- | | | | | | | | | | | | | |
| | tion | | | | | | | | | | | | | |
| | C₂H₄/SiH₄ | [—] | 0.00 | 0.00 | 0.00 | 0.00 | 0.00 | 0.00 | 0.00 | 0.00 | 0.00 | 0.00 | 0.50 | 1.50 |
| | Discharge | [Ncm/s] | 71.0 | 71.0 | 94.7 | 94.8 | 94.7 | 94.6 | 71.0 | 94.7 | 71.0 | 142.0 | 78.8 | 63.1 |
| | flow rate | | | | | | | | | | | | | |
| Process | O₂ | [mol %] | 100 | 100 | 100 | 100 | 100 | 100 | 100 | 100 | 100 | 100 | 100 | 100 |
| gas 2 | concentra- | | | | | | | | | | | | | |
| | tion | | | | | | | | | | | | | |
| | Discharge | [Ncm/s] | 35.5 | 35.5 | 23.7 | 23.7 | 23.7 | 23.7 | 35.5 | 23.7 | 35.5 | 71.0 | 19.7 | 15.8 |
| | flow rate | | | | | | | | | | | | | |

| | | | | | | | | | | | | | |
|---|---|---|---|---|---|---|---|---|---|---|---|---|---|
| SiH₄ flow rate per | [NL/ | 0.26 | 0.34 | 0.51 | 0.68 | 0.85 | 1.02 | 1.28 | 1.36 | 1.53 | 2.05 | 0.85 | 0.91 |
| unit width | min · m] | | | | | | | | | | | | |
| O₂/SiH₄ | [—] | 500.0 | 375.0 | 166.7 | 125.0 | 100.0 | 83.0 | 100.0 | 62.5 | 83.3 | 125.0 | 83.3 | 62.5 |
| Substrate | [deg. C.] | 586 | 582 | 594 | 594 | 558 | 594 | 570 | 594 | 570 | 570 | 585 | 560 |
| temperature | | | | | | | | | | | | | |
| Deposition rate | [nm · m/ | 130.3 | 201.7 | 318.5 | 335.7 | 376.8 | 382.5 | 397.0 | 401.2 | 401.8 | 395.7 | 372.2 | 406.5 |
| | min] | | | | | | | | | | | | |

TABLE 2-1

| | | | Ex. 1 | Ex. 2 | Ex. 3 | Ex. 4 | Ex. 5 | Ex. 6 | Ex. 7 | Ex. 8 | Ex. 9 | Ex. 10 |
|---|---|---|---|---|---|---|---|---|---|---|---|---|
| Process | SiH₄ | [mol %] | 1.75 | 1.28 | 0.72 | 1.50 | 1.50 | 1.75 | 1.50 | 1.28 | 1.50 | 1.50 |
| gas 1 | concentration | | | | | | | | | | | |
| | C₂H₄ | [mol %] | 0.35 | 0.26 | 0.36 | 0.75 | 0.75 | 0.88 | 0.75 | 0.64 | 1.50 | 1.50 |
| | concentration | | | | | | | | | | | |
| | C₂H₄/SiH₄ | [—] | 0.20 | 0.20 | 0.50 | 0.50 | 0.50 | 0.50 | 0.50 | 0.50 | 1.00 | 1.00 |
| | Discharge | [Ncm/s] | 71.0 | 118.4 | 79.0 | 59.2 | 71.0 | 71.0 | 94.7 | 118.4 | 47.3 | 59.2 |
| | flow rate | | | | | | | | | | | |
| Process | O₂ | [mol %] | 100 | 100 | 100 | 100 | 100 | 100 | 100 | 100 | 100 | 100 |
| gas 2 | concentration | | | | | | | | | | | |
| | Discharge | [Ncm/s] | 35.5 | 35.5 | 19.7 | 29.6 | 35.5 | 35.5 | 47.3 | 35.5 | 23.7 | 29.6 |
| | flow rate | | | | | | | | | | | |

| | | | | | | | | | | | |
|---|---|---|---|---|---|---|---|---|---|---|---|
| SiH₄ flow rate per unit | [NL/min · m] | 2.24 | 2.73 | 1.02 | 1.60 | 1.92 | 2.24 | 2.56 | 2.73 | 1.28 | 1.60 |
| width | | | | | | | | | | | |
| O₂/SiH₄ | [—] | 57.1 | 46.9 | 69.4 | 66.6 | 66.7 | 57.1 | 66.7 | 46.9 | 66.7 | 66.6 |
| Substrate temperature | [deg. C.] | 570 | 570 | 585 | 570 | 570 | 570 | 570 | 570 | 570 | 570 |
| Deposition rate | [nm · m/min] | 443.7 | 445.9 | 431.6 | 521.0 | 600.9 | 572.4 | 789.9 | 619.0 | 462.4 | 594.3 |

TABLE 2-2

| | | | Ex. 11 | Ex. 12 | Ex. 13 | Ex. 14 | Ex. 15 | Ex. 16 | Ex. 17 | Ex. 18 | Ex. 19 | Ex. 20 |
|---|---|---|---|---|---|---|---|---|---|---|---|---|
| Process | SiH₄ | [mol %] | 1.50 | 1.50 | 1.00 | 1.50 | 1.20 | 1.00 | 1.50 | 1.50 | 1.07 | 1.50 |
| gas 1 | concentration | | | | | | | | | | | |
| | C₂H₄ | [mol %] | 1.50 | 1.50 | 1.50 | 2.25 | 1.80 | 1.50 | 2.25 | 2.25 | 1.60 | 2.25 |
| | concentration | | | | | | | | | | | |
| | C₂H₄/SiH₄ | [—] | 1.00 | 1.00 | 1.50 | 1.50 | 1.50 | 1.50 | 1.50 | 1.50 | 1.50 | 1.50 |
| | Discharge | [Ncm/s] | 71.0 | 94.7 | 63.1 | 47.3 | 63.1 | 78.8 | 59.2 | 71.0 | 118.4 | 94.7 |
| | flow rate | | | | | | | | | | | |
| Process | O₂ | [mol %] | 100 | 100 | 100 | 100 | 100 | 100 | 100 | 100 | 100 | 100 |
| gas 2 | concentration | | | | | | | | | | | |
| | Discharge | [Ncm/s] | 35.5 | 47.3 | 15.8 | 23.7 | 15.8 | 19.7 | 29.6 | 35.5 | 35.5 | 47.3 |
| | flow rate | | | | | | | | | | | |

| | | | | | | | | | | | |
|---|---|---|---|---|---|---|---|---|---|---|---|
| SiH₄ flow rate per unit | [NL/min · m] | 1.92 | 2.56 | 1.14 | 1.28 | 1.36 | 1.42 | 1.60 | 1.92 | 2.27 | 2.56 |
| width | | | | | | | | | | | |
| O₂/SiH₄ | [—] | 66.7 | 66.7 | 50.0 | 66.7 | 41.7 | 50.0 | 66.6 | 66.7 | 56.3 | 66.7 |
| Substrate temperature | [deg. C.] | 570 | 570 | 561 | 570 | 561 | 594 | 570 | 570 | 547 | 570 |
| Deposition rate | [nm · m/min] | 706.8 | 845.0 | 470.5 | 505.0 | 521.9 | 533.7 | 610.1 | 736.7 | 787.8 | 826.0 |

TABLE 2-3

| | | | Ex. 21 | Ex. 22 | Ex. 23 | Ex. 24 | Ex. 25 | Ex. 26 | Ex. 27 | Ex. 28 | Ex. 29 |
|---|---|---|---|---|---|---|---|---|---|---|---|
| Process | SiH₄ | [mol %] | 1.28 | 1.50 | 1.50 | 1.50 | 1.50 | 1.50 | 1.28 | 1.28 | 1.50 |
| gas 1 | concentration | | | | | | | | | | |
| | C₂H₄ | [mol %] | 1.92 | 3.00 | 3.00 | 3.00 | 3.00 | 3.60 | 3.01 | 3.83 | 4.80 |
| | concentration | | | | | | | | | | |
| | C₂H₄/SiH₄ | [—] | 1.50 | 2.00 | 2.00 | 2.00 | 2.00 | 2.40 | 2.35 | 3.00 | 3.20 |
| | Discharge | [Ncm/s] | 118.4 | 47.3 | 59.2 | 71.0 | 94.7 | 47.3 | 118.4 | 118.4 | 47.3 |
| | flow rate | | | | | | | | | | |
| Process | O₂ | [mol %] | 100 | 100 | 100 | 100 | 100 | 100 | 100 | 100 | 100 |
| gas 2 | concentration | | | | | | | | | | |
| | Discharge | [Ncm/s] | 35.5 | 23.7 | 29.6 | 35.5 | 47.3 | 23.7 | 35.5 | 35.5 | 23.7 |
| | flow rate | | | | | | | | | | |

| | | | | | | | | | | |
|---|---|---|---|---|---|---|---|---|---|---|
| SiH₄ flow rate per unit | [NL/min · m] | 2.73 | 1.28 | 1.60 | 1.92 | 2.56 | 1.28 | 2.73 | 2.73 | 1.28 |
| width | | | | | | | | | | |
| O₂/SiH₄ | [—] | 46.9 | 66.7 | 66.6 | 66.7 | 66.7 | 66.7 | 46.9 | 46.9 | 66.7 |
| Substrate temperature | [deg. C.] | 547 | 570 | 570 | 570 | 570 | 570 | 570 | 570 | 570 |
| Deposition rate | [nm · m/min] | 831.4 | 459.2 | 593.3 | 720.6 | 725.8 | 430.0 | 809.1 | 744.6 | 431.4 |

TABLE 3

| | | | Ex. 30 | Ex. 31 | Ex. 32 | Ex. 33 | Ex. 34 | Ex. 35 | Ex. 36 | Ex. 37 | Ex. 38 | Ex. 39 |
|---|---|---|---|---|---|---|---|---|---|---|---|---|
| Process | SiH₄ | [mol %] | 0.80 | 1.00 | 0.60 | 0.80 | 0.95 | 1.20 | 1.40 | 1.50 | 1.67 | 1.75 |
| gas 1 | concentration | | | | | | | | | | | |
| | C₂H₄ | [mol %] | 1.20 | 1.50 | 0.90 | 1.20 | 1.43 | 1.80 | 2.10 | 1.50 | 1.33 | 1.40 |
| | concentration | | | | | | | | | | | |
| | C₂H₄/SiH₄ | [—] | 1.50 | 1.50 | 1.50 | 1.50 | 1.50 | 1.50 | 1.50 | 1.00 | 0.80 | 0.80 |
| | Discharge | [Ncm/s] | 78.9 | 63.1 | 126.3 | 94.7 | 78.9 | 63.1 | 78.8 | 71.0 | 71.0 | 71.0 |
| | flow rate | | | | | | | | | | | |
| Process | O₂ | [mol %] | 100 | 100 | 100 | 100 | 100 | 100 | 100 | 100 | 100 | 100 |
| gas 2 | concentration | | | | | | | | | | | |
| | Discharge | [Ncm/s] | 19.7 | 15.8 | 31.6 | 23.7 | 19.7 | 15.8 | 19.7 | 35.5 | 35.5 | 35.5 |
| | flow rate | | | | | | | | | | | |

| | | | | | | | | | | | |
|---|---|---|---|---|---|---|---|---|---|---|---|
| SiH₄ flow rate per unit | [NL/min · m] | 1.14 | 1.14 | 1.36 | 1.36 | 1.35 | 1.36 | 1.99 | 1.92 | 2.13 | 2.24 |
| width | | | | | | | | | | | |
| O₂/SiH₄ | [—] | 62.5 | 50.0 | 83.3 | 62.5 | 52.6 | 41.7 | 35.7 | 66.7 | 60.0 | 57.1 |
| Substrate temperature | [deg. C.] | 559 | 560 | 561 | 555 | 555 | 560 | 563 | 570 | 570 | 570 |
| Deposition rate | [nm · m/min] | 427.2 | 456.2 | 428.9 | 463.3 | 478.2 | 527.6 | 631.6 | 619.7 | 538.9 | 526.0 |

TABLE 4

| | | | Ex. 40 | Ex. 41 | Ex. 42 |
|---|---|---|---|---|---|
| Process | SiH₄ | [mol %] | 1.40 | 1.40 | 1.28 |
| gas 1 | concentration | | | | |
| | C₂H₄ | [mol %] | 1.75 | 1.75 | 1.92 |
| | concentration | | | | |
| | C₂H₄/SiH₄ | [—] | 1.25 | 1.25 | 1.50 |
| | Discharge | [Ncm/s] | 94.7 | 94.7 | 118.4 |
| | flow rate | | | | |
| Process | O₂ | [mol %] | 60 | 100 | 11 |
| gas 2 | concentration | | | | |
| | Discharge | [Ncm/s] | 23.7 | 23.7 | 35.5 |
| | flow rate | | | | |

| | | | | |
|---|---|---|---|---|
| SiH₄ flow rate per unit | [NL/min · m] | 2.39 | 2.39 | 2.73 |
| width | | | | |
| O₂/SiH₄ | [—] | 21.4 | 35.7 | 5.1 |
| Substrate temperature | [deg. C.] | 545 | 545 | 570 |
| Deposition rate | [nm · m/min] | 557.7 | 633.5 | 552.2 |

TABLE 5

| Wavelength (nm) | Refractive index |
|---|---|
| 354.24 | 1.4887 |
| 364.66 | 1.487 |
| 375.71 | 1.4854 |
| 387.45 | 1.4839 |
| 399.95 | 1.4824 |
| 413.28 | 1.481 |
| 427.54 | 1.4796 |
| 442.8 | 1.4783 |
| 459.2 | 1.4771 |
| 476.87 | 1.4758 |
| 495.94 | 1.4747 |
| 516.61 | 1.4735 |
| 539.07 | 1.4724 |
| 563.57 | 1.4714 |
| 590.41 | 1.4704 |
| 619.93 | 1.4694 |
| 652.55 | 1.4684 |
| 688.81 | 1.4675 |
| 729.33 | 1.4666 |
| 774.91 | 1.4657 |
| 826.57 | 1.4648 |
| 885.61 | 1.4638 |
| 953.73 | 1.4628 |
| 1033.21 | 1.4618 |
| 1127.14 | 1.4606 |
| 1239.85 | 1.4593 |

### INDUSTRIAL APPLICABILITY

The SiO₂ thin film formed by the method of the present invention is useful for a various functional film to be formed on a glass substrate, specifically as a layer constituting a part of an antireflection film, a layer constituting a part of a ultraviolet (UV) blocking multilayer structure, a layer constituting a part of an infrared (IR) blocking multilayer structure, a surface layer for Low-E (Low-emissivity) glass excellent in heat-shielding properties or a reflection amplifying layer of a sunlight collecting glass, or at the time of producing a thin film type solar cell, it is useful also as a various functional film to be formed on a glass substrate constituting a transparent substrate for the thin film type solar cell, specifically as an alkali barrier layer or as an intermediate refractive index layer formed between a glass substrate and a tin oxide film constituting a transparent conductive film. Thus, the SiO₂ thin film formed by the method of the present invention can be used for e.g. architectural glass, vehicle glass for e.g. automobiles, glass for displays, optical elements, cover glass for solar cells, show-window glass, optical glass and eyeglass lenses.

This application is a continuation of PCT Application No. PCT/JP2013/081673, filed on Nov. 25, 2013, which is based upon and claims the benefit of priority from Japanese Patent Application No. 2012-257227 filed on Nov. 26, 2012. The contents of those applications are incorporated herein by reference in their entireties.

### REFERENCE SYMBOLS

10: Raw material gas supply means

12: Roller conveyor

12a: Conveyor roller

14: Outlet for process gas 1

16: Outlet for process gas 2

18: Exhaust nozzle

Z: Glass substrate

What is claimed is:

1. A method for forming a SiO₂ thin film on a glass substrate by an online atmospheric pressure CVD method, which uses, as a raw material gas supply means, a post mixing type raw material supply means of separately supplying a process gas 1 which contains monosilane (SiH₄) as a main raw material gas and a process gas 2 which contains oxygen (O₂) as an auxiliary raw material gas and mixing the process gases 1 and 2 on the glass substrate, wherein the flow rate of the monosilane (SiH₄) per unit width is at least 1.0 NL/min·m, and the process gas 1 contains ethylene (C₂H₄) in an amount such that the concentration ratio to the monosilane (SiH₄) (C₂H₄ (mol %)/SiH₄ (mol %)) is at most 3.2.

2. The method for forming a SiO₂ thin film according to claim 1, wherein the process gas 1 contains ethylene (C₂H₄) in an amount such that the concentration ratio to the monosilane (SiH₄) (C₂H₄ (mol %)/SiH₄ (mol %)) is from 0.2 to 3.2.

3. The method for forming a SiO₂ thin film according to claim 1, wherein the process gas 1 contains ethylene (C₂H₄) in an amount such that the concentration ratio to the monosilane (SiH₄) (C₂H₄ (mol %)/SiH₄ (mol %)) is from 0.5 to 3.2.

4. The method for forming a SiO₂ thin film according to claim 1, wherein the flow rate of the monosilane (SiH₄) per unit width is at least 1.5 NL/min·m.

5. The method for forming a SiO₂ thin film according to claim 1, wherein the process gas 1 is a mixed gas comprising monosilane (SiH₄, ethylene (C₂H₄) and an inert gas, and the concentration of the monosilane (SiH₄) in the process gas 1 is from 0.2 to 2 mol %.

6. The method for forming a SiO₂ thin film according to claim 1, wherein the process gas 1 is a mixed gas comprising monosilane (SiH₄), ethylene (C₂H₄) and an inert gas, and the concentration of the monosilane (SiH₄) in the process gas 1 is from 0.6 to 1.75 mol %.

7. The method for forming a SiO₂ thin film according to claim 1, wherein the process gas 1 is a mixed gas comprising monosilane (SiH₄), ethylene (C₂H₄) and an inert gas, and the concentration of the monosilane (SiH₄) in the process gas 1 is from 0.6 to 1.5 mol %.

8. The method for forming a SiO₂ thin film according to claim 1, wherein the molar ratio of the oxygen (O₂) in the process gas 2 to the monosilane (SiH₄) in the process gas 1 (O₂/SiH₄) is at least 5.

9. The method for forming a SiO₂ thin film according to claim 1, wherein the deposition rate for the SiO₂ thin film is at least 425 nm·m/min.
